(19) United States
(12) Patent Application Publication
(10) Pub. No.: US 2007/0297146 A1
(43) Pub. Date: Dec. 27, 2007

(54) Data Communications with an Integrated Circuit

(76) Inventors: John E. Campbell, Wappingers Falls, NY (US); Kevin C. Gower, LaGrangeville, NY (US); Steven W. Roth, Oronoco, MN (US); Gary A. Tressler, Sandy Hood, CT (US)

Correspondence Address: IBM (ROC-BLF), C/O BIGGERS & OHANIAN, LLP, P.O. BOX 1469, AUSTIN, TX, 78767-1469, US

(21) Appl. No.: 11/426,643

(22) Filed: Jun. 27, 2006

(51) Int. Cl. H05K 7/00

(52) U.S. Cl. 361/728

(57) ABSTRACT

Systems are disclosed in which a first receiver circuit of an integrated circuit die, the die having conductive die pads for electrical signal transfer between conductive pathways inside the die and conductive pathways outside the die, the first receiver circuit having an input connected to a first die pad and an output connected to a first logic circuit of the die and a second receiver circuit of the integrated circuit die, the second receiver circuit having an input connected to a second die pad and an output connected to a second logic circuit of the integrated circuit die, where both receiver circuits are configured to receive the same signals.

### BACKGROUND OF THE INVENTION

1. Field of the Invention

The field of the invention is data processing, or, more specifically, systems for data communications with integrated circuits.

2. Description Of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago. One area of computer technology that has become very sophisticated is computer memory. Today many high performance computing main memory systems use multiple memory modules with multiple memory devices connected to a controller in one or more ‘channels.’ Many systems utilize cascaded logic devices, called ‘hubs’ or ‘buffers,’ to buffer memory controller signals and drive cascaded signals up and down a memory controller channel. Such buffers may reside upon one or be connected to one or more memory modules containing memory devices.

Such sophisticated memory systems, however, are not without remaining technological issues. An unrepaired fault in the channel of a typical cascaded memory system prevents accesses to all memory devices that are downstream of the fault, that is, further from the memory controller than the fault. Also, cascaded buffer chips are designed to perform both local as well as cascaded communications operations, and the logical macros that perform these operations may be physically separated on the buffer chip.

### SUMMARY OF THE INVENTION

Systems are disclosed in which a first receiver circuit of an integrated circuit die, the die having conductive die pads for electrical signal transfer between conductive pathways inside the die and conductive pathways outside the die, the first receiver circuit having an input connected to a first die pad and an output connected to a first logic circuit of the die and a second receiver circuit of the integrated circuit die, the second receiver circuit having an input connected to a second die pad and an output connected to a second logic circuit of the integrated circuit die, where both receiver circuits are configured to receive the same signals.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a line drawing and block diagram illustrating an exemplary system for data communications with an integrated circuit according to embodiments of the present invention.

FIG. 2 sets forth a line drawing and block diagram illustrating a further exemplary system for data communications with an integrated circuit according to embodiments of the present invention.

FIG. 3 sets forth a line drawing and block diagram illustrating a further exemplary system for data communications with an integrated circuit according to embodiments of the present invention.

FIG. 4 sets forth a line drawing and block diagram illustrating a further exemplary system for data communications with an integrated circuit according to embodiments of the present invention.

FIG. 5 sets forth a line drawing and block diagram illustrating a further exemplary system for data communications with an integrated circuit according to embodiments of the present invention.

FIG. 6 sets forth a line drawing and block diagram illustrating a further exemplary system for data communications with an integrated circuit according to embodiments of the present invention.

FIG. 7 sets forth a line drawing and block diagram illustrating a further exemplary system for data communications with an integrated circuit according to embodiments of the present invention.

FIG. 8 sets forth a line drawing and block diagram illustrating a further exemplary system for data communications with an integrated circuit according to embodiments of the present invention.

FIG. 9 sets forth a line drawing and block diagram illustrating a further exemplary system for data communications with an integrated circuit according to embodiments of the present invention.

### DETAILED DESCRIPTION OF EXEMPLARY EMBODIMENTS

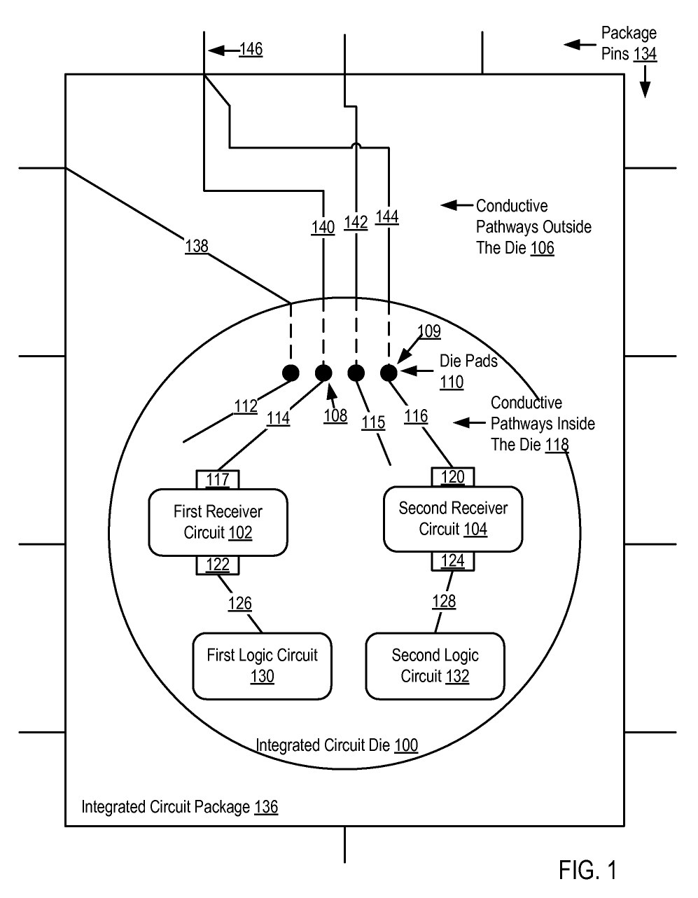

Exemplary systems for data communications with an integrated circuit according to embodiments of the present invention are described with reference to the accompanying drawings, beginning with FIG. 1. FIG. 1 sets forth a line drawing and block diagram illustrating an exemplary system for data communications with an integrated circuit according to embodiments of the present invention that includes an integrated circuit die (100) encapsulated in an integrated circuit package (136).

An integrated circuit die typically is a form of integrated circuit formed on a substrate made of a mono-crystalline silicon wafer (although in some applications the substrate wafer may be formed of silicon on sapphire, gallium arsenide, or other materials) by photolithography, deposition, and etching. Photolithography is used to mark different areas of the substrate to be doped or to have polysilicon, insulators or metal (typically aluminum) tracks deposited on them. Many integrated circuits may be formed on a single wafer.

Each integrated circuit on the wafer is tested before packaging. The wafer is then cut into small rectangles called ‘dice’ (singular ‘die’). Each die is then connected into a package using aluminum (or occasionally gold) wires which are welded to pads, usually installed around the edge of the die. Traces out of the die, through the package, and into the printed circuit board have very different electrical properties, compared to on-die signals. They require special design techniques and need much more electric power than signals confined to the chip itself.

Early integrated circuits were packaged in ceramic flat packs, which continued to be used by the military for their reliability and small size for many years. Commercial circuit packaging quickly moved to the dual in-line package (‘DIP’), first in ceramic and later in plastic. In the 1980s pin counts of very large scale integration (‘VLSI’) circuits exceeded the practical limit for DIP packaging, leading to pin grid array (‘PGA’) and leadless chip carrier (‘LCC’) packages.

Surface mount packaging appeared in the early 1980s and became popular in the late 1980s, using finer lead pitch with leads formed as either gull-wing or J-lead, as exemplified by small-outline integrated circuits (‘SOIC’), a carrier which occupies an area about thirty to fifty percent less than an equivalent DIP, also typically about seventy percent thinner than an equivalent DIP. The SOIC package has ‘gull wing’ leads protruding from the two long sides and a lead spacing of 0.050 inches.

Other package technologies useful in systems for data communications with an integrated circuit according to embodiments of the present invention include ‘PLCC’ which stands for Plastic Leaded Chip Carrier. PLCCs are four sided “J” Leaded Plastic body packages. Lead counts range from 20 to 84. PLCC packages can be square or rectangle. Body widths range from 0.35″ to 1.15″. PLCCs are JEDEC standard compliant. The PLCC “J” Lead configuration requires less board space compared to equivalent gull leaded components.

Other package technologies useful in systems for data communications with an integrated circuit according to embodiments of the present invention include ball grid arrays (‘BGAs’). A BGA is a surface-mount packaging for an integrated circuit descended from the pin grid array (‘PGA’), a package with one face covered (or partly covered) with pins in a grid pattern. These pins are used to conduct electrical signals from an integrated circuit die to a printed circuit board (‘PCB’) on which the die is placed. In a BGA, the pins are replaced by balls of solder stuck to the bottom of the package. The die is placed on a PCB that carries copper pads in a pattern that matches the solder balls. The assembly is then heated, either in a reflow oven or by an infrared heater, causing the solder balls to melt. Surface tension causes the molten solder to hold the package in alignment with the circuit board, at the correct separation distance, while the solder cools and solidifies. The composition of the solder alloy and the soldering temperature are carefully chosen so that the solder does not completely melt, but stays semi-liquid, allowing each ball to stay separate from its neighbors. The BGA is a solution to the problem of producing a miniature package for an integrated circuit with many hundreds of pins.

This disclosure has now discussed several ways of implementing integrated circuit packages in systems for data communications with an integrated circuit according to embodiments of the present invention. Other ways of implementing integrated circuit package in systems for data communications with an integrated circuit according to embodiments of the present invention will occur to those of skill in the art, and all such ways are well within the scope of the present invention.

The die (100) in the system of FIG. 1 includes two receiver circuits (102, 104). A receiver circuit is a specialized form of input circuit, an electronic circuit on an integrated circuit die designed to receive, buffer, improve, and deliver to other circuits of the die electronic signals from outside the die. Such a receiver circuit only receives and delivers signals, performing no functional logic or data processing as such. A receiver circuit is designed to buffer incoming signals by providing optimum input impedance for signal transmission paths from outside the die. Signal arriving in the die, often at very high frequencies, may have become quite degraded through transmission. A receiver circuit is designed also therefore to improve a signal that may have become degraded with voltage comparators, high slew rate gain stages, and the like, so that the signal delivered by the receiver circuit more closely resembles the square wave desirable for digital data processing within the die.

The two receiver circuits in integrated circuit die (100) are represented as a first receive circuit (102) and a second receiver circuit (104). The die in this example has conductive die pads (110) for electrical signal transfer between conductive pathways (118) inside the die and conductive pathways (106) outside the die. The first receiver circuit (102) has an input (117) connected to a first die pad (108) and an output (122) connected to a first logic circuit (130) of the die. The second receiver circuit (104) has an input (120) connected to a second die pad (109) and an output (124) connected to a second logic circuit (132) of the integrated circuit die (100). Each logic circuit may be a data processing circuit in a System-On-A-Chip (‘SOC’), for example, part of an input/output function of a microcontroller or embedded system, a memory device in a memory module, and so on. The inclusion of two receiver circuits in this example is for explanation only, not a limitation of the invention. Any number of receiver circuits as may occur to those of skill in the art may be included in an integrated circuit die in systems for data communications with an integrated circuit according to embodiments of the present invention.

In the example system of FIG. 1 die (100) is encapsulated in an integrated circuit package (136), the integrated circuit package having conductive pins (134) connected to pads (110) of the die, and both receiver circuits (102, 104) are configured to receive and communicate to both logic circuits (130, 132) the same signals. In this example, both receiver circuit inputs (117, 120) are connected through separate die pads (108, 109) and separate package wires (140, 144) to a single package pin (146). The same input signal is therefore delivered to both receiver inputs (117, 120). For ease of explanation, each receiver circuit is illustrated in this example with a single input line (114, 116). Readers will recognize, however, that each receiver may have many input lines deliver the same parallel or parallel/serial signals, typically, for example, depending on the particular application, 4, 8, 16, 32, or even 64 or more input lines.

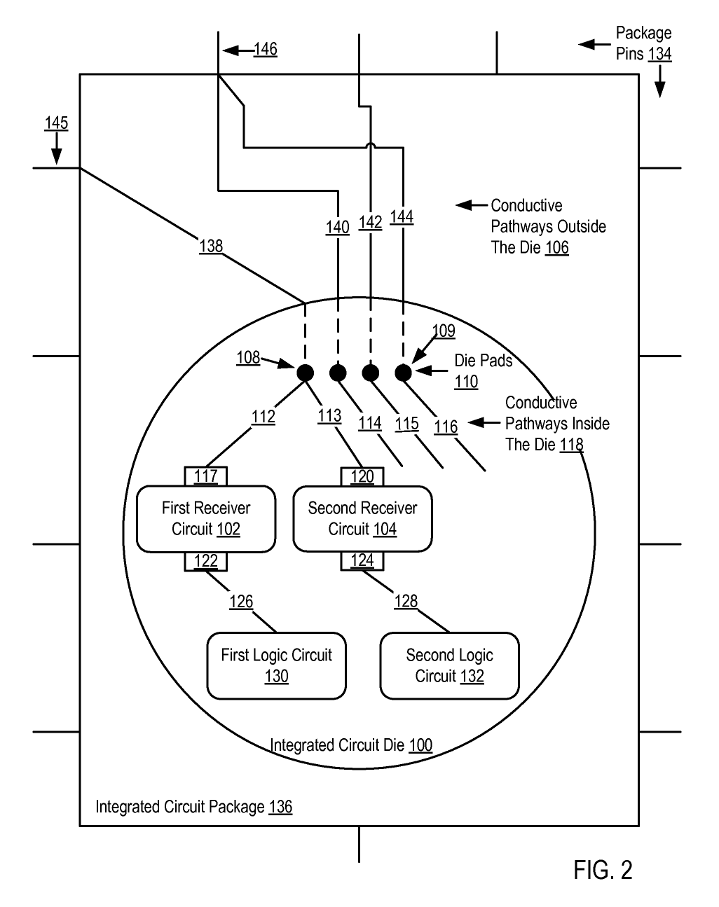

For further explanation, FIG. 2 sets forth a line drawing and block diagram illustrating a further exemplary system for data communications with an integrated circuit according to embodiments of the present invention. The system of FIG. 2 is similar to the system of FIG. 1, including as it does an integrated circuit die (100) installed in an integrated circuit package (136), the die including two receiver circuits (102, 104) configured to receive and deliver the same signals to two logic circuits (130, 132).

In the system of FIG. 2, however, both receiver circuit inputs (117, 120) are connected (112, 113) only to a first die pad (108). In the system of FIG. 1, the receiver circuit inputs are connected to separate die pads (114, 116) but to the same package pin (146). Both the system of FIG. 1 and the system of FIG. 2 deliver the same input signal to the receiver inputs (117, 120) and thereafter to the logic circuits (130, 132), but the physical transmission paths are different, giving system designers more options. Input signals in the system of FIG. 2 encounter only a single conductive pathway (138) between package pin (145) and die pad (108) and only a single physical connection at die pad (108). Input signals in the system of FIG. 1, however, encounter two conductive pathways (140, 144) between package pin (146) and die pads (108, 109) and two physical connections at the die pads. The two conductive pathways (140, 144) may add parallel inductance and the two physical connections at the die pads (108, 109) may add parallel capacitance - by comparison with the transmission path of the system of FIG. 2.

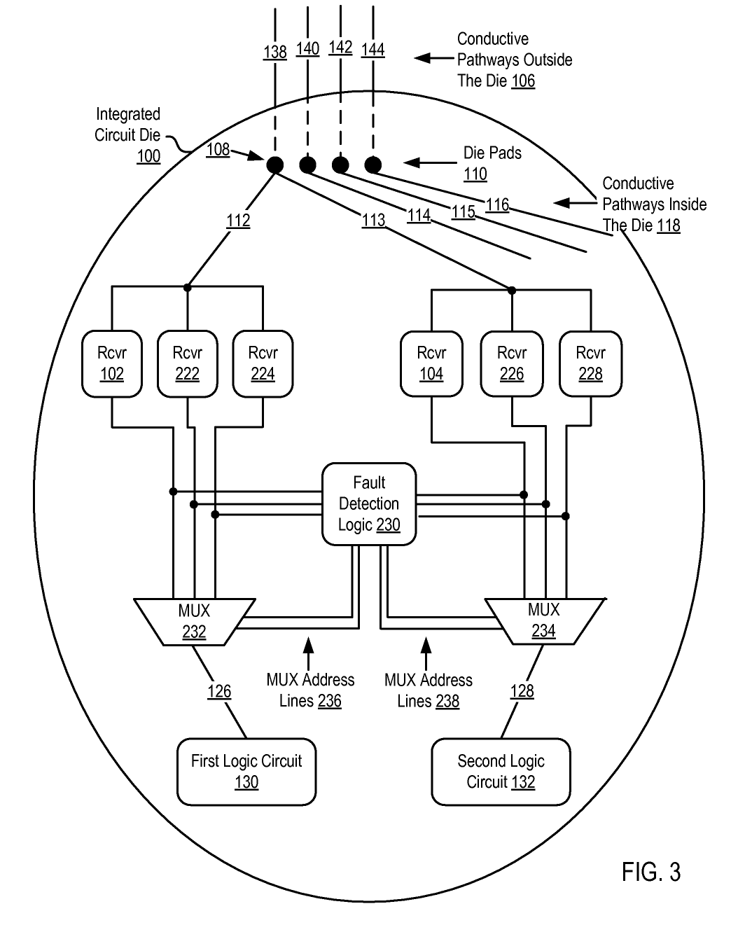

For further explanation, FIG. 3 sets forth a line drawing and block diagram illustrating a further exemplary system for data communications with an integrated circuit according to embodiments of the present invention. The system of FIG. 3 is similar to the system of FIG. 2, including as it does an integrated circuit die (100), the die including two receiver circuits (102, 104) configured to receive and communicate the same signals to two logic circuits (130, 132). In the system of FIG. 3, like the system of FIG. 2, both receiver circuit inputs are connected (112, 113) only to a single die pad (108). No packaging is shown for the die in FIG. 3. The die may be encapsulated in an integrated circuit package, wire bonded to a printed circuit board, wire bonded to a planar device such as a motherboard or backplane, or installed otherwise as may occur to those of skill in the art.

The die in the system of FIG. 3 includes four receiver circuits (222, 224, 226, 228) in addition to the first and second receiver circuits (102, 104). The die of FIG. 3 also includes two multiplexers (232, 234) and fault detection logic (230) for detecting receiver failure. In the example of FIG. 3, each receiver circuit (102, 104) is grouped with two other receiver circuits (222, 224, and 226, 228 respectively) to form two groups of three redundant receiver circuits, one each for delivery of the same signal to first logic circuit (130) and second logic circuit (132) respectively. That is, receivers (102, 222, 224) are grouped with their inputs connected and their outputs multiplexed to deliver an input signal (108, 112, 126) to first logic circuit (130), and receiver circuits (104, 226, 228) are grouped with their inputs connected and their outputs multiplexed to deliver the same input signal (108, 113, 128) to second logic circuit (132).

When fault detection logic (230) detects a failure among receiver circuits (102, 222, 224), fault detection logic may increment the address on multiplexer address lines (236), thereby selecting the output of another receiver circuit from the group (102, 222, 224) for delivery to first logic circuit (130). When fault detection logic (230) detects a failure among receiver circuits (104, 226, 228) fault detection logic may increment the address on multiplexer address lines (238), thereby selecting the output of another receiver circuit from the group (104, 226, 228) for deliver to second logic circuit (132). In this way, all three receiver circuits of a group must fail before either logic circuit loses its input signal. Both logic circuits will continue to receive their input signal even in the face of complete failure of as many as four receiver circuits, two from each group. The integrated circuit on die (100) in the example of FIG. 3 is very robust with respect to data communications among circuits on the die.

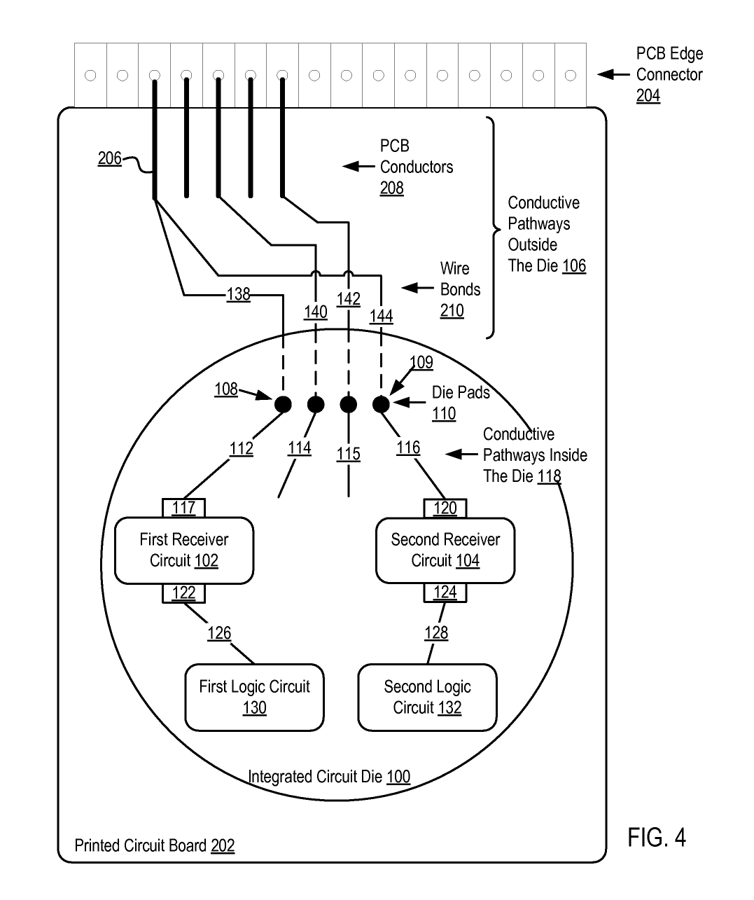

For further explanation, FIG. 4 sets forth a line drawing and block diagram illustrating a further exemplary system for data communications with an integrated circuit according to embodiments of the present invention. The system of FIG. 4 is similar to the system of FIG. 1, including as it does an integrated circuit die (100), the die including two receiver circuits (102, 104) that receive and deliver the same signals to two logic circuits (130, 132). The first receiver circuit has an input (117) connected to a first die pad (108) and an output (122) connected to a first logic circuit (130) of the die. The second receiver circuit (104) has an input (120) connected to a second die pad (109) and an output (124) connected to a second logic circuit (132) of the integrated circuit die (100).

In the system of FIG. 4, however, the die is not installed in an integrated circuit package as was done in the system of FIG. 1. In the system of FIG. 4, the die (100) is installed directly on a printed circuit board (202) with no integrated circuit packaging on the die. Also unlike the system of FIG. 1, in the system of FIG. 4, the receiver circuit inputs (117, 120) are not connected through separate die pads (108, 109) and separate package wires (140, 144) to a single package pin (146 on FIG. 1). In the system of FIG. 4, both receiver circuit inputs (117, 120) are connected (112, 116) through separate die pads (108, 109) and separate wire bonds (138, 144) to a single printed circuit board conductor (206). In the example of FIG. 4, the printed circuit board conductor (206) is connected to a printed circuit board edge connector (204) which may be plugged into a peripheral bus slot or backplane slot for connection to a larger system.

In an alternative structure for the system of FIG. 4, PCB conductors (208) may be extended to die pads (110), that is, to the location where the die pads will contact the PCB when integrated circuit die (100) is installed upon the PCB. Such an alternative structure may be implemented with a so-called ‘flip chip’ by replacing the wire bonds (210) with ball grid array (‘BGA’) bonds on the side of the integrated circuit package that contacts the PCB, underfilling the integrated circuit die on the PCB with an epoxy, and placing solder balls on the ball grid array. The integrated circuit die is then ‘flipped’ over onto the PCB and the solder is melted.

In addition, interconnections between a integrated circuit die or an integrated circuit die installed upon a printed circuit board or other planar substrate and other components of a larger system may be implemented in various ways as may occur to those of skill in the art, including for example, solder interconnects, conductive adhesives, socket structures, pressure contacts and other methods which enable communication electronic components of a system through electrical, optical or alternate means. Such interconnections may include mating connectors (male/female), conductive contacts and/or pins on one carrier mating with a male or female connector, optical connections, pressure contacts (including a retaining mechanism) and/or one or more of various other communication and power delivery methods. Conductive elements of such interconnections may be disposed along one or more edges of a printed circuit board, module, or planar device and/or placed a distance from an edge of a printed circuit board, module, or planar device—depending on such application requirements as ease-of-upgrade/repair, available space/volume, heat transfer, component size and shape and other related physical, electrical, optical, and visual or physical access requirements of any particular installation.

Input signals in the system of FIG. 4, encounter two conductive pathways (206, 138, 112 and 206, 144, 116) between edge connector (204) and die pads (108, 109). In addition, input signals in the system of FIG. 4 encounter physical connection at each end of wire bonds (138, 144). The two conductive pathways may add parallel inductance and the physical connections at each end of the wire bonds may add parallel capacitance—by comparison with the transmission path of the system of FIG. 2—for example.

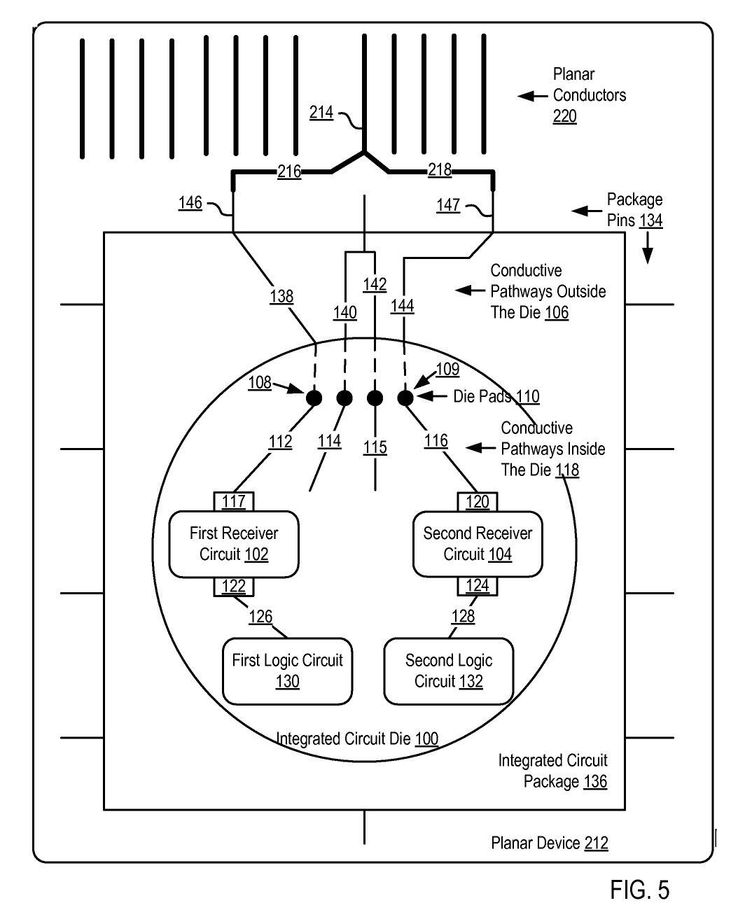

For further explanation, FIG. 5 sets forth a line drawing and block diagram illustrating a further exemplary system for data communications with an integrated circuit according to embodiments of the present invention. The system of FIG. 5 is similar to the system of FIG. 1, including as it does an integrated circuit die (100) installed in an integrated circuit package (136), the die including two receiver circuits (102, 104) that receive and deliver the same signals to two logic circuits (130, 132). The first receiver circuit has an input (117) connected to a first die pad (108) and an output (122) connected to a first logic circuit (130) of the die. The second receiver circuit (104) has an input (120) connected to a second die pad (109) and an output (124) connected to a second logic circuit (132) of the integrated circuit die (100).

In the system of FIG. 5, however, the die (100) is encapsulated in an integrated circuit package (136) mounted on a planar device (212). The integrated circuit package has conductive pins (134) connected to pads (110) of the die, and the planar device includes planar conductors (220). In the system of FIG. 5, both receiver circuit inputs (117, 120) are connected (112, 116) through separate die pads (108, 109), separate conductive pins (146, 147), and separate planar conductors (216, 218) to a single planar conductor (214).

Planar conductors (220) may be implemented as lands, pads, or vias fabriacted upon or within layers of a planar device such as a printed circuit board, a motherboard, or a backplane. Planar conductors are a mode of interconnection between an integrated circuit die in an integrated circuit package and other components of a larger system. In addition, however, such interconnections between a integrated circuit die in an integrated circuit package other components of a larger system may be implemented in various ways as may occur to those of skill in the art, including for example, solder interconnects, conductive adhesives, socket structures, pressure contacts and other methods which enable communication among electronic components of a system through electrical, optical or alternate means. Such interconnections may include mating connectors (male/female), conductive contacts and/or pins on one carrier mating with a male or female connector, optical connections, pressure contacts (including a retaining mechanism) and/or one or more of various other communication and power delivery methods. Conductive elements of such interconnections may be disposed along one or more edges of a printed circuit board, module, or planar device and/or placed a distance from an edge of a printed circuit board, module, or planar device - depending on such application requirements as ease-of-upgrade/repair, available space/volume, heat transfer, component size and shape and other related physical, electrical, optical, and visual or physical access requirements of any particular installation.

Input signals in the example system of FIG. 5, encounter two conductive pathways (214, 216, 146, 138, and 214, 218, 147, 144,) between planar conductor (214) and die pads (108, 109). In addition, input signals in the system of FIG. 5 encounter physical connections:
at the junctions between planar conductors (216, 218) and package pins (146, 147),
at the junctions between package pins (146, 147) and package conductors (138, 144), and
at the junctions between package conductors (138, 144) and die pads (108, 109).

The two conductive pathways may add parallel inductance and the physical connections in the paths may add parallel capacitance—by comparison with the transmission path of the system of FIG. 2—for example.

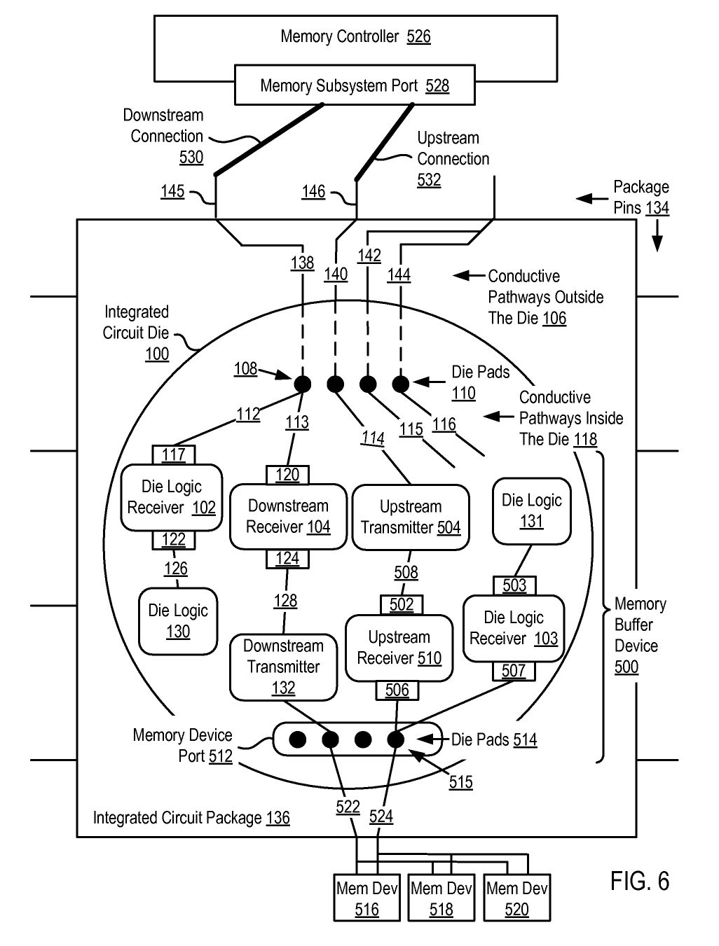

For further explanation, FIG. 6 sets forth a line drawing and block diagram illustrating a further exemplary system for data communications with an integrated circuit according to embodiments of the present invention that includes a memory controller (526), an integrated circuit die (100) encapsulated in an integrated circuit package (136), and several memory devices (516, 518, 520). The memory controller (526) and circuitry of the integrated circuit die (100) are connected (530, 532) for data communications, and circuitry of the integrated circuit die is connected for data communications to the memory devices (516, 518, 520).

Connections (530, 532) for data communications between a memory controller (526) and circuitry of an integrated circuit die (100) in an integrated circuit package (136) may be implemented in various ways as may occur to those of skill in the art, including for example, solder interconnects, conductive adhesives, socket structures, pressure contacts and other methods which enable communication among electronic components of a system through electrical, optical or alternate means. Such connections may include mating connectors (male/female), conductive contacts and/or pins on one carrier mating with a male or female connector, optical connections, pressure contacts (including a retaining mechanism) and/or one or more of various other communication and power delivery methods. Conductive elements of such connections may be disposed along one or more edges of a printed circuit board, module, or planar device and/or placed a distance from an edge of a printed circuit board, module, or planar device - depending on such application requirements as ease-of-upgrade/repair, available space/volume, heat transfer, component size and shape and other related physical, electrical, optical, and visual or physical access requirements of any particular installation. Such connections may be implemented with bus structures, with point-to-point interconnections, or with other structures as may occur to those of skill in the art.

Memory controller (526) is a memory management unit, a computer hardware component responsible for handling memory accesses requested by a computer processor. Among the functions of such devices are the translation of virtual addresses to physical addresses (i.e., virtual memory management), memory protection, cache control, and data communications (reading and writing computer data) with physical memory.

In the example of FIG. 6, memory controller (526) includes a memory subsystem port (528). Memory subsystem port (528) provides input/output functionality between memory controller (526) and a memory subsystem. In the system of FIG. 6, all components except the memory controller represent a memory subsystem. For clarity of explanation, only one memory subsystem port and only one memory subsystem are included in the example of FIG. 6, but a memory controller for data communications with an integrated circuit according to embodiments of the present invention may include any number of memory subsystem ports and any number of memory subsystems.

Data communications connections (530, 532) between the memory subsystem port (528) and the memory subsystem, for clarity of explanation, are shown as single signal lines. Readers will recognize, however, that such connections will typically include a plurality of control and data lines. Data communications connections (530, 532) between the memory subsystem port (528) and the memory subsystem in this example are characterized as a unidirectional downstream connection (530) and a unidirectional upstream connection (532). Taken together, unidirectional downstream connection (530) and unidirectional upstream connection (532) make up a complete bidirectional data communications connection between memory subsystem port (528) and the memory subsystem in this example. In this context ‘downstream’ means data communications in a direction away from memory controller (526) and towards memory devices (516, 518, 520), and ‘upstream’ means data communications in a direction away from memory devices (516, 518, 520) and toward memory controller (526).

In this example, each memory device (516, 518, 520) is represented as a DRAM. Such a DRAM may be a Fast Page Mode (‘FPM’) DRAM, a Video DRAM (‘VRAM’), an Extended Data Out (‘EDO’) DRAM, a Burst EDO (‘BEDO’) DRAM, a Synchronous DRAM (‘SDRAM’), a Direct Rambus DRAM (‘DRDRAM’), a Single Data Rate (‘SDR’) DRAM, a Double Data Rate (‘DDR’) SDRAM, and so on, as will occur to those of skill in the art. In addition, readers will recognize the use of DRAM in the examples in this specification is for explanation only, not a limitation of the present invention. In fact, systems for data communications with an integrated circuit according to embodiments of the present invention may be implemented with static random access memory or with any other kind of RAM as may occur to those of skill in the art.

In the system of FIG. 6, circuitry of the die (100) is configured as a memory buffer device (500). Memory buffer device (500) includes a memory device port (512) connected for data communications to memory devices (516, 518, 520). That is, memory devices (516, 518, 520) are connected (522, 524) for data communications to memory buffer device (500) through memory device port (512). Memory device port (512) provides input/output functionality between memory buffer device (500) and memory devices (516, 518, 520). Data communications connection (522, 524) between the memory device port (512) and memory devices (516, 518, 520), for clarity of explanation, are shown as single signal lines. Readers will recognize, however, that such connections will typically include a plurality of control and data lines including, for example, DRAM control lines such as Column Address Strobe (‘CAS’), Row Address Strobe (‘RAS’), and Write Enable (‘WE’). Memory buffer device (500) provides logic to temporarily store data written to and read from memory devices and to encode and decode memory addresses so that several memory devices appear to a memory controller as a single memory device.

The die (100) in the system of FIG. 6 includes a first receiver circuit (102) represented in this example as a die logic receiver that communicates a signal received through die pad (106) to functional logic circuitry (130) on the die. The die (100) in the system of FIG. 6 also includes a second receiver circuit (104) represented in this example as a downstream receiver circuit that communicates a signal received through die pad (106) to downstream transmitter circuit (132) for transmission to a memory device (516, 518, 520).

The integrated circuit die (100) in this example has conductive die pads (110, 514) for electrical signal transfer between conductive pathways (118) inside the die and conductive pathways (106) outside the die. Die logic receiver circuit (102) has an input (117) connected to die pad (108) and an output (122) connected to a logic circuit (130) of the die. Memory subsystem port includes a downstream signal line (530) connected (145, 138) for data communications to die pad (108). Downstream receiver circuit (104) has an input (120) connected to the same die pad (108) as the input (117) to die logic receiver (102). Downstream receiver circuit (104) has an output (124) connected to downstream transmitter circuit (132). Die logic receiver circuit (102) and downstream receiver circuit (104) both are configured to receive the same signals and deliver the same received signals from memory controller (526) to die logic (130) and to downstream transmitter circuit (132).

In addition to the first and second receivers (102, 104), the example system of FIG. 6 also includes a third receiver represented as an upstream receiver circuit (510) that delivers signals received from memory devices (516, 518, 520) to an upstream transmitter circuit (504) for transmission to memory controller (526). The example system of FIG. 6 also includes a fourth receiver represented as a die logic receiver that communicates a signal received from memory devices (516, 518, 520) to functional logic circuitry (131) on the die. Die logic receiver circuit (103) has an input (507) connected to die pad (515) and an output (503) connected to a logic circuit (131) of the die. Upstream receiver circuit (510) has an input (506) connected to the same die pad (515) as the input (507) to die logic receiver (103). Upstream receiver circuit (510) has an output (502) connected to upstream transmitter circuit (504). Upstream receiver circuit (510) and die logic receiver circuit (103) both deliver the same received signals from memory devices (516, 518, 520) to upstream transmitter circuit (504) and to die logic (131).

The inclusion of four receiver circuits in the example system of FIG. 6 is for explanation only, not a limitation of the invention. Any number of receiver circuits as may occur to those of skill in the art may be included in an integrated circuit die in systems for data communications with an integrated circuit according to embodiments of the present invention.

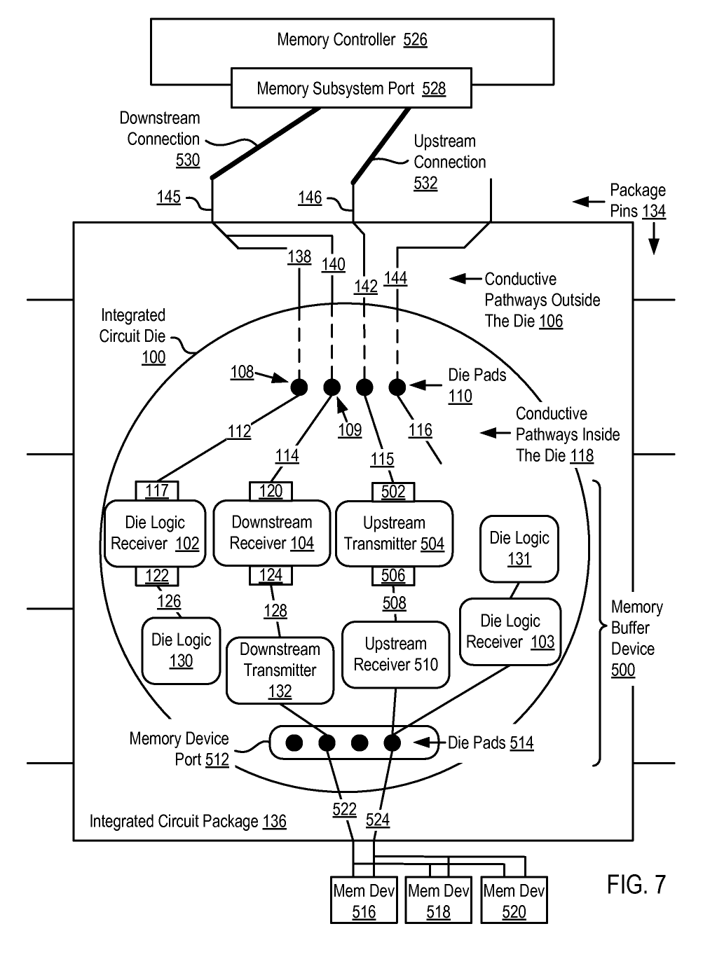

For further explanation, FIG. 7 sets forth a line drawing and block diagram illustrating a further exemplary system for data communications with an integrated circuit according to embodiments of the present invention. The system of FIG. 7 is similar to the system of FIG. 6, including as it does an integrated circuit die (100) with circuitry of the die configured as a memory buffer device (500). The memory buffer device has a memory device port (512). The memory buffer device includes several receivers and transmitters configured to provide downstream and upstream data communications between memory devices and a memory controller, just as in the example of FIG. 6. The system of FIG. 7, also like the system of FIG. 6, includes a memory controller (526) with a memory subsystem port (528). The system of FIG. 7, also like the system of FIG. 6, includes memory devices (516, 518, 520) connected (522, 524) for data communications to memory buffer device (500) through memory device port (512).

In the system of FIG. 7, the die (100) is encapsulated in an integrated circuit package (136), and the integrated circuit package has conductive pins (134) connected to pads (110, 514) of the die. In the system of FIG. 6, receiver circuit inputs (117, 120) for die logic receiver (102) and downstream receiver (104) are connected (112, 113) to the same die pad (108). In the system of FIG. 7, however, receiver circuit inputs (117, 120) are connected (112, 114) to separate die pads (108, 109) but to the same package pin (145). In the system of FIG. 7, memory subsystem port (528) includes a signal line (530) connected for data communications to package pin (145). Die logic receiver circuit (102) and downstream receiver circuit (104) both are configured to receive the same signals and deliver the same received signals from memory controller (526) to die logic (130) and to downstream transmitter circuit (132).

Both the system of FIG. 6 and the system of FIG. 7 deliver the same input signal to the receiver inputs (117, 120) and thereafter to die logic (130) and to downstream transmitter (132), but the physical transmission paths are different, giving system designers more options. Input signals in the system of FIG. 6 encounter only a single conductive pathway (138) between package pin (145) and die pad (108) and only a single physical connection at die pad (108). Input signals in the system of FIG. 7, however, encounter two conductive pathways (138, 140) between package pin (145) and die pads (108, 109) and two physical connections at the die pads, that is, one physical connection on each die pad for a total of two. The two conductive pathways (138, 140) may add parallel inductance and the two physical connections at the die pads (108, 109) may add parallel capacitance—by comparison with the transmission path of the system of FIG. 6.

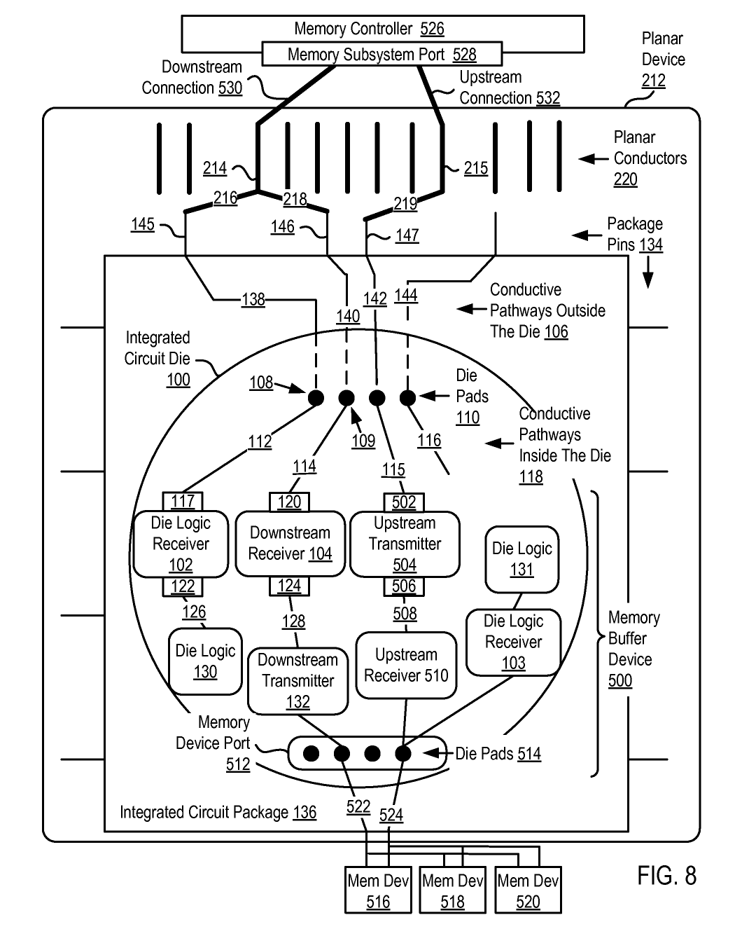

For further explanation, FIG. 8 sets forth a line drawing and block diagram illustrating a further exemplary system for data communications with an integrated circuit according to embodiments of the present invention. The system of FIG. 8 is similar to the system of FIG. 6, including as it does an integrated circuit die (100) with circuitry of the die configured as a memory buffer device (500). The memory buffer device has a memory device port (512). The memory buffer device includes several receivers and transmitters configured to provide downstream and upstream data communications between memory devices and a memory controller, just as in the example of FIG. 6. The system of FIG. 8, also like the system of FIG. 6, includes a memory controller (526) with a memory subsystem port (528). The system of FIG. 8, also like the system of FIG. 6, includes memory devices (516, 518, 520) connected (522, 524) for data communications to memory buffer device (500) through memory device port (512).

In the system of FIG. 8, the die (100) is encapsulated in an integrated circuit package (136) mounted on a planar device (212). The integrated circuit package has conductive pins (134) connected to pads (110, 514) of the die, and the planar device includes planar conductors (220). In the system of FIG. 6, receiver circuit inputs (117, 120) for die logic receiver (102) and downstream receiver (104) are connected (112, 113) to the same die pad (108). In the system of FIG. 8, however, receiver circuit inputs (117, 120) are connected (112, 114) to separate die pads (108, 109), to separate package pins (145, 146), to separate interim planar conductors (216, 218), but to the same planar conductor (214). In the system of FIG. 8, memory subsystem port (528) includes a signal line (530) connected for data communications to planar conductor (214). Die logic receiver circuit (102) and downstream receiver circuit (104) both are configured to receive the same signals and deliver the same received signals from memory controller (526) to die logic (130) and to downstream transmitter circuit (132).

Both the system of FIG. 6 and the system of FIG. 8 deliver the same input signal to receiver inputs (117, 120) and thereafter to die logic (130) and to downstream transmitter (132), but the physical transmission paths are different, giving system designers more options. A downstream signal in the system of FIG. 6 encounters only a single conductive pathway (530, 145, 138) between memory subsystem port (528) and die pad (108). The same downstream signal in the system of FIG. 6 encounters only three physical connections between memory subsystem port (528) and die pad (108):
between memory subsystem port (528) and downstream connection (530),
between downstream connection (530) and package pin (145), and
between internal conductive path (138) and die pad (108).

A downstream signal in the system of FIG. 8, however, encounters two conductive pathway (530, 214, 216, 145, 138 and 530, 214, 218, 146, 140) between memory subsystem port (528) and die pads (108, 109). The downstream signal in the system of FIG. 8, moreover, encounters six physical connections between memory subsystem port (528) and die pads (108, 109):
between memory subsystem port (528) and downstream connection (530),
between downstream connection (530) and planar conductor (214),
between planar conductor (214) and package pin (145),
between internal conductive path (138) and die pad (108),
between planar conductor (218) and package pin (146), and
between internal conductive path (140) and die pad (109).

The two conductive pathways (530, 214, 216, 145, 138 and 530, 214, 218, 146, 140) may add parallel inductance and the additional physical connections in the transmission path may add parallel capacitance—by comparison with the transmission path of the system of FIG. 6.

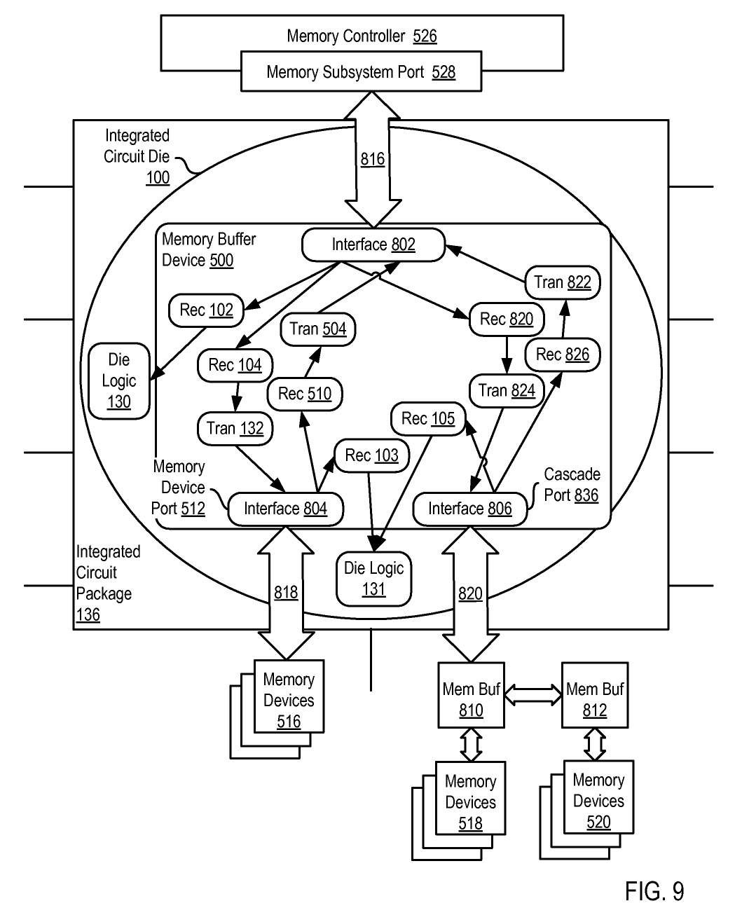

For further explanation, FIG. 9 sets forth a line drawing and block diagram illustrating a further exemplary system for data communications with an integrated circuit according to embodiments of the present invention. In the system of FIG. 9, circuitry of the die (100) is configured as a memory buffer device (500). The system of FIG. 9 includes memory devices (516) connected for data communications to memory buffer device (500) through memory device port (512), represented here as interface (804). The system of FIG. 9 also includes memory buffer devices (810, 812) connected in cascade to memory buffer device (500) through cascade port (836), represented here as interface (806). In the example of FIG. 9, the memory buffer device (500) receives a signal from a memory subsystem port (528) of a memory controller (526) at two receivers (104, 820). One receiver (104) communicates with memory devices (516) associated with the memory buffer device (500), and the other receiver (820) communicates with a cascaded memory buffer device (810).

The memory buffer device (500) in the example of FIG. 9 includes several interfaces (802, 804, 806). Memory buffer device (500) includes interface (802) connected (816) to memory subsystem port (528) of memory controller (526). Memory buffer device (500) also includes interface (804) connected (818) to memory devices (516). Memory buffer device (500) also includes interface (806) connected (820) to second memory buffer device (810). Each interface is composed of all the connecting conductive pathways and physical connections among conductive pathways inside the die (100), conductive pathways outside the die, package pins, planar conductors, die pads, and the like, required for data communications across connections to and from memory buffer device (500).

Connections (816) for data communications between a memory controller (526) and circuitry of an integrated circuit die (100) in an integrated circuit package (136) may be implemented in various ways as may occur to those of skill in the art, including for example, solder interconnects, conductive adhesives, socket structures, pressure contacts and other methods which enable communication among electronic components of a system through electrical, optical or alternate means. Such connections may include mating connectors (male/female), conductive contacts and/or pins on one carrier mating with a male or female connector, optical connections, pressure contacts (including a retaining mechanism) and/or one or more of various other communication and power delivery methods. Conductive elements of such connections may be disposed along one or more edges of a printed circuit board, module, or planar device and/or placed a distance from an edge of a printed circuit board, module, or planar device—depending on such application requirements as ease-of-upgrade/repair, available space/volume, heat transfer, component size and shape and other related physical, electrical, optical, and visual or physical access requirements of any particular installation. Such connections may be implemented with bus structures, with point-to-point interconnections, or with other structures as may occur to those of skill in the art.

In the example of FIG. 9, the portion of interface (804) required for data communications with memory devices (516) is referred to as a memory device port (512). Similarly, the portion of interface (806) required for data communications between memory buffer device (500) and cascaded second memory buffer device (810) is referred to as a cascade port (836). Any number of additional memory buffer devices, represented here by cascaded memory buffer device (812), may be added in cascade for data communications with memory buffer device (500) and memory controller (526).

In the example of FIG. 9, interfaces (802, 804, 806) are connected for data communications through several receivers (102, 104, 510, 103, 820, 826, 105) and several transmitters (132, 504, 824, 822) that communicate to the memory device (516) and to the second memory buffer device (810) signals received from the memory controller (526) and communicate to the memory controller (526) signals received from the memory device (516) and from the second memory buffer device (810). More particularly: Receiver (102) communicates to memory buffer device (500) at die logic circuit (130) signals received from the memory controller (526). Receiver (104) and transmitter (132) communicate to memory device (516) signals received from memory controller (526). Receiver (820) and transmitter (824) communicate to second memory buffer device (810) signals received from the memory controller (526). Receiver (103) communicates to memory buffer device (500) at die logic circuit (131) signals received from memory devices (516). Receiver (510) and transmitter (504) communicate to memory controller (526) signals received from memory devices (516). Receiver (105) communicates to memory buffer device (500) at die logic circuit (131) signals received from second memory buffer device (810). And receiver (826) and transmitter (822) communicate to memory controller (526) signals received from second memory buffer device (810).

In downstream communications, interface (802) delivers the same signal equally from memory controller (526) to receivers (102, 104, 820) and therefore also the same signal to die logic (130), to memory devices (516), to cascaded memory buffer devices (810, 812), and to further memory devices (518, 520). Receivers (102, 104, 820) are configured to receive the same signals and deliver the same received signals from memory controller (526) to die logic (130), to downstream transmitter circuit (132), and to transmitter (824).

In upstream communications, memory device port (512) delivers the same signal equally from memory devices (516) to receivers (510, 103) and therefore also the same signal to die logic (131) and to memory controller (526). Receivers (510, 103) both are configured to receive the same signals and deliver the same received signals from memory device port (512) to die logic (131) and to memory controller (526). Also in upstream communications, cascade port (836) delivers the same signal equally from cascaded memory buffer devices (810, 812), and therefore also from memory devices (518, 520), to receivers (105, 826) and therefore also the same signal to die logic (131) and to memory controller (526). Receivers (105, 826) both are configured to receive the same signals and deliver the same received signals from cascade port (836) to die logic (131) and to memory controller (526).

In view of the explanations set forth above, readers will appreciate that the advantages of implementing memory systems (and other systems for data communications with integrated circuits) according to embodiments of this invention include the use of multiple receiver circuits within cascaded memory buffer devices and memory controller for the memory channel signals. The receivers may be used to separately capture incoming local signals and cascaded signals. If one receiver fails, the others may continue to function thereby limiting the impact of the fault on the availability of the modules within the memory system. This capability increases the fault tolerance and robustness of the main memory system. Also, by using multiple receiver circuits and pathways, the signals may be quickly delivered to differing areas on the receiving package. This minimizes memory system latency. This capability is also very useful for highly integrated ‘systems on a chip’ which include multiple circuit macros which receive and/or deliver information to/from its chip to chip signaling.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A system for data communications with an integrated circuit comprising:
a first receiver circuit of an integrated circuit die, the die having conductive die pads for electrical signal transfer between conductive pathways inside the die and conductive pathways outside the die, the first receiver circuit having an input connected to a first die pad and an output connected to a first logic circuit of the die; and
a second receiver circuit of the integrated circuit die, the second receiver circuit having an input connected to a second die pad and an output connected to a second logic circuit of the integrated circuit die;
wherein both receiver circuits are configured to receive the same signals.

2. The system of claim 1 wherein:
the die is encapsulated in an integrated circuit package, the integrated circuit package having conductive pins connected to pads of the die; and
both receiver circuit inputs are connected through separate die pads and separate package wires to a single package pin.

3. The system of claim 1 wherein both receiver circuit inputs are connected only to the first die pad.

4. The system of claim 1 wherein:
the die is installed directly on a printed circuit board with no integrated circuit packaging on the die; and
both receiver circuit inputs are connected through separate die pads and separate wire bonds to a single printed circuit board conductor.

5. The system of claim 1 wherein:
the die is installed directly on a printed circuit board with no integrated circuit packaging on the die; and
both receiver circuit inputs are connected through separate die pads and separate ball grid array (‘BGA’) bonds to a single printed circuit board conductor.

6. The system of claim 1 wherein:
the die is encapsulated in an integrated circuit package mounted on a planar device, the integrated circuit package having conductive pins connected to pads of the die, the planar device comprising planar conductors; and
both receiver circuit inputs are connected through separate die pads and separate conductive pins to a single planar conductor.

7. The system of claim 1 wherein circuitry of the die is configured as a memory buffer device, the memory buffer device has a memory device port, both receiver circuit inputs are connected to the first die pad, and the system further comprises:
a memory controller having a memory subsystem port, the memory subsystem port including a signal line connected for data communications to the first die pad; and
at least one memory device is connected for data communications to the memory buffer device through the memory device port.

8. The system of claim 1 wherein circuitry of the die is configured as a memory buffer device, the memory buffer device has a memory device port, the die is encapsulated in an integrated circuit package, the integrated circuit package has conductive pins connected to pads of the die, both receiver circuit inputs are connected through separate die pads to a first package pin, and the system further comprises:
a memory controller having a memory subsystem port, the memory subsystem port including a signal line connected for data communications to the first package pin; and
at least one memory device connected for data communications to the memory buffer device through the memory device port.

9. The system of claim 1 wherein circuitry of the die is configured as a memory buffer device, the memory buffer device has a memory device port, the die is encapsulated in an integrated circuit package mounted on a planar device, the integrated circuit package has conductive pins connected to pads of the die, the planar device comprises planar conductors, both receiver circuit inputs are connected through separate die pads and package pins to a first planar conductor, and the system further comprises:
a memory controller having a memory subsystem port, the memory subsystem port including a signal line connected for data communications to the first planar conductor; and
at least one memory device connected for data communications to the memory buffer device through the memory device port.

10. The system of claim 1 wherein circuitry of the die is configured as a memory buffer device, the memory buffer device further comprising:
a first interface connected to a memory subsystem port of a memory controller;
a second interface connected to at least one memory device; and
a third interface connected to a second memory buffer device,
wherein the interfaces are connected for data communications through a plurality of receivers and a plurality of transmitters that communicate to the memory device and to the second memory buffer device signals received from the memory controller and communicate to the memory controller signals received from the memory device and from the second memory buffer device.

11. The system of claim 1 wherein circuitry of the die is configured as a memory buffer device that receives a signal from a memory subsystem port of a memory controller at two receivers, one receiver for communicating with memory devices associated with the memory buffer device and another receiver for communicating with a cascaded memory buffer device.

12. The system of claim 1 further comprising:
a first receiver circuit group of the integrated circuit die, the first receiver circuit group comprising the first receiver circuit and at least one additional receiver circuit with inputs of the receiver circuits in the first receiver circuit group connected to one another and outputs of the receiver circuits in the first receiver group connected to a first multiplexer that selects an output from a first one of the receiver circuits of the first receiver circuit group so as to deliver an input signal to the first logic circuit.

13. The system of claim 12 wherein circuitry of the die further comprises fault detection logic capable of detecting a fault in the operation of the first one of the receiver circuits of the first receiver circuit group and addressing the first multiplexer to select an output from a second one of the receiver circuits of the the first receiver circuit group so as to continue to deliver the input signal to the first logic circuit.

14. The system of claim 12 further comprising:
a second receiver circuit group of the integrated circuit die, the second receiver circuit group comprising the second receiver circuit and at least one additional receiver circuit with inputs of the receiver circuits in the second receiver circuit group connected to one another and also connected to the inputs of the receiver circuits in the first receiver group and outputs of the receiver circuits in the second receiver group connected to a second multiplexer that selects an output from one of the receiver circuits of the second receiver circuit group so as to deliver the input signal to the second logic circuit.

15. The system of claim 14 wherein circuitry of the die further comprises fault detection logic capable of detecting a fault in the operation of the first one of the receiver circuits of the second receiver circuit group and addressing the second multiplexer to select an output from a second one of the receiver circuits of the second receiver circuit group so as to continue to deliver the input signal to the second logic circuit.

16. A system for data communications with an integrated circuit comprising:
a first receiver circuit of an integrated circuit die, the die having conductive die pads for electrical signal transfer between conductive pathways inside the die and conductive pathways outside the die, the first receiver circuit having an input connected to a first die pad and an output connected to a first logic circuit of the die; and
a second receiver circuit of the integrated circuit die, the second receiver circuit having an and an output connected to a second logic circuit of the integrated circuit die;
wherein both receiver circuits are configured to receive the same signals.

17. The system of claim 1 wherein:
the die is encapsulated in an integrated circuit package, the integrated circuit package having conductive pins connected to pads of the die; and
both receiver circuit inputs are connected through separate die pads and separate package wires to a single package pin.

18. The system of claim 1 wherein both receiver circuit inputs are connected only to the first die pad.

19. The system of claim 1 wherein:
the die is installed directly on a printed circuit board with no integrated circuit packaging on the die; and
both receiver circuit inputs are connected through separate die pads and separate wire bonds to a single printed circuit board conductor.

20. The system of claim 1 wherein:
the die is installed directly on a printed circuit board with no integrated circuit packaging on the die; and
both receiver circuit inputs are connected through separate die pads and separate ball grid array (‘BGA’) bonds to a single printed circuit board conductor.

21. The system of claim 1 wherein:
the die is encapsulated in an integrated circuit package mounted on a planar device, the integrated circuit package having conductive pins connected to pads of the die, the planar device comprising planar conductors; and
both receiver circuit inputs are connected through separate die pads and separate conductive pins to a single planar conductor.

22. The system of claim 1 wherein circuitry of the die is configured as a memory buffer device, the memory buffer device has a memory device port, both receiver circuit inputs are connected to the first die pad, and the system further comprises:
a memory controller having a memory subsystem port, the memory subsystem port including a signal line connected for data communications to the first die pad; and
at least one memory device is connected for data communications to the memory buffer device through the memory device port.

23. The system of claim 1 wherein circuitry of the die is configured as a memory buffer device, the memory buffer device has a memory device port, the die is encapsulated in an integrated circuit package, the integrated circuit package has conductive pins connected to pads of the die, both receiver circuit inputs are connected through separate die pads to a first package pin, and the system further comprises:
a memory controller having a memory subsystem port, the memory subsystem port including a signal line connected for data communications to the first package pin; and
at least one memory device connected for data communications to the memory buffer device through the memory device port.

24. The system of claim 1 wherein circuitry of the die is configured as a memory buffer device, the memory buffer device has a memory device port, the die is encapsulated in an integrated circuit package mounted on a planar device, the integrated circuit package has conductive pins connected to pads of the die, the planar device comprises planar conductors, both receiver circuit inputs are connected through separate die pads and package pins to a first planar conductor, and the system further comprises:
a memory controller having a memory subsystem port, the memory subsystem port including a signal line connected for data communications to the first planar conductor; and
at least one memory device connected for data communications to the memory buffer device through the memory device port.

25. The system of claim 1 wherein circuitry of the die is configured as a memory buffer device, the memory buffer device further comprising:
a first interface connected to a memory subsystem port of a memory controller;
a second interface connected to at least one memory device; and
a third interface connected to a second memory buffer device,
wherein the interfaces are connected for data communications through a plurality of receivers, including the first receiver and the second receiver, and a plurality of transmitters that communicate to the memory device and to the second memory buffer device signals received from the memory controller and communicate to the memory controller signals received from the memory device and from the second memory buffer device.

26. The system of claim 1 wherein circuitry of the die is configured as a memory buffer device that receives a signal from a memory subsystem port of a memory controller at the first receiver and the second receiver, the first receiver connected to communicate with memory devices associated with the memory buffer device and the second receiver connected to communicate with a cascaded memory buffer device.

27. The system of claim 1 further comprising:
a first receiver circuit group of the integrated circuit die, the first receiver circuit group comprising the first receiver circuit and at least one additional receiver circuit with inputs of the receiver circuits in the first receiver circuit group connected to one another and outputs of the receiver circuits in the first receiver group connected to a first multiplexer that selects an output from a first one of the receiver circuits of the first receiver circuit group so as to deliver an input signal to the first logic circuit.

28. The system of claim 12 wherein circuitry of the die further comprises fault detection logic capable of detecting a fault in the operation of the first one of the receiver circuits of the first receiver circuit group and addressing the first multiplexer to select an output from a second one of the receiver circuits of the the first receiver circuit group so as to continue to deliver the input signal to the first logic circuit.

29. The system of claim 12 further comprising:
a second receiver circuit group of the integrated circuit die, the second receiver circuit group comprising the second receiver circuit and at least one additional receiver circuit with inputs of the receiver circuits in the second receiver circuit group connected to one another and also connected to the inputs of the receiver circuits in the first receiver group and outputs of the receiver circuits in the second receiver group connected to a second multiplexer that selects an output from one of the receiver circuits of the second receiver circuit group so as to deliver the input signal to the second logic circuit.

30. The system of claim 14 wherein circuitry of the die further comprises fault detection logic capable of detecting a fault in the operation of the first one of the receiver circuits of the second receiver circuit group and addressing the second multiplexer to select an output from a second one of the receiver circuits of the second receiver circuit group so as to continue to deliver the input signal to the second logic circuit.
